(19) United States
(12) Patent Application Publication
(10) Pub. No.: US 2026/0105218 A1
(43) Pub. Date: Apr. 16, 2026

(54) SYSTEMS AND METHODS FOR ENGINEERING OPTIMIZATION USING QUANTUM COMPUTING

(71) Applicant: BOSONQ PSI CORP., Syracuse, NY (US)

(72) Inventors: Abhishek CHOPRA, Buffalo, NY (US); Rut LINESWALA, Latrobe, PA (US); Jash MINOCHA, Syracuse, NY (US)

(21) Appl. No.: 19/120,774

(22) PCT Filed: Oct. 28, 2023
(86) PCT No.: PCT/US2023/078129

§ 371 Date: Apr. 13, 2025

(30) Foreign Application Priority Data
Oct. 28, 2022 (IN) 202221061418
Oct. 28, 2022 (IN) 202221061420

(51) Int. Cl. G06F 30/27; G06N 10/20; G06N 10/60; G06N 10/80

(52) U.S. Cl. CPC G06F 30/27; G06N 10/20; G06N 10/60; G06N 10/80

(57) ABSTRACT

Methods and systems herein may solve engineering problems, such as multiphysics problems as design optimization problems, using quantum computing. Such quantum computing may utilize a quantum computing system, which may include a classical computing processor and a quantum processor. The classical computing processor may be configured to provide instructions to and receive output from the quantum processor. The quantum processor may comprise one or more quantum bits manipulated and measured by a quantum bit interface module. Input and a model comprising a quantum algorithm for an engineering problem may be used by the classical computing processor to generate quantum input for the quantum processor, which may operate using the quantum input, and quantum output may be returned to the classical computing processor to determine the output of the engineering model. In some implementations, an error may be determined and an error correction applied to the engineering model.

### CROSS REFERENCE TO RELATED APPLICATIONS

This application claims priority to Indian Provisional Application No. 202221061418, filed on 28 Oct. 2022 and Indian Provisional Application No. 202221061420, filed on 28 Oct. 2022, the entire disclosures of which are hereby incorporated by reference.

### BACKGROUND

Solving certain engineering problems (e.g., design optimization, multiphysics) involve continuous and simultaneous interdependent calculations along with error correction.

Design optimization may comprise the systematic process of refining a design to meet specified objectives while adhering to given constraints. By utilizing mathematical models, algorithms, and computational techniques, engineers can identify design solutions among a set of alternatives. The aims of design optimization may include to achieve improved performance, efficiency, or other desired criteria, ensuring the design is both functional and cost-effective.

Multiphysics simulation may comprise computational modeling of multiple interacting physical phenomena within a single framework. Instead of examining a single physical field (e.g., fluid dynamics or electromagnetism) in isolation, multiphysics simulations may enable engineers and scientists to capture the interdependence and coupling between different fields, providing a more comprehensive understanding of real-world scenarios.

### SUMMARY

This Summary is intended to introduce, in an abbreviated form, various topics to be elaborated upon below in the Detailed Description. This Summary is not intended to identify key or essential aspects of the claimed invention. This Summary is similarly not intended for use as an aid in determining the scope of the claims.

Implementations herein may provide for solving engineering problems (e.g., design problems, computer-aided engineering simulations), such as multiphysics problems as design optimization problems, using quantum computing. Such quantum computing may utilize a quantum computing system, which may include a classical computing processor and a quantum processor. The classical computing processor may be configured to provide instructions to and receive output from the quantum processor. The quantum processor may comprise one or more quantum bits manipulated and measured by a quantum bit interface module. Input and a model comprising a quantum algorithm for an engineering problem may be used by the classical computing processor to generate quantum input for the quantum processor, which may operate using the quantum input, and quantum output may be returned to the classical computing processor to determine the output of the engineering model. In some implementations, an error may be determined and an error correction applied to the engineering model.

### BRIEF DESCRIPTION OF THE FIGURES

For a fuller understanding of the nature and objects of the disclosure, reference should be made to the following detailed description taken in conjunction with the accompanying drawings, in which:

FIG. 1 illustrates a quantum computing system for solving engineering problems using quantum computing, according to one or more implementations herein;

FIG. 2 illustrates an operational environment, according to one or more implementations;

FIG. 3 illustrates a diagram of example components of one or more devices of FIGS. 1-2, according to one or more implementations;

FIG. 4 illustrates a flowchart for solving an engineering problem, according to one or more implementations;

FIG. 5 illustrates a flowchart for solving an engineering problem and determining an error correction, according to one or more implementations;

FIG. 6 illustrates a flowchart for solving an engineering problem with error correction applied, according to one or more implementations;

FIG. 7 illustrates an artificial neural network (ANN), according to one or more implementations;

FIG. 8 illustrates a node, according to one or more implementations;

FIG. 9 illustrates a method of training a machine learning model of a machine learning module, according to one or more implementations; and

FIG. 10 illustrates a method of analyzing input data using a machine learning module, according to one or more implementations; and

FIG. 11 may illustrate an example solution process of a multiphysics problem, according to one or more implementations herein.

### DETAILED DESCRIPTION

It is to be understood that the invention is not limited in its application to the details of construction and the arrangements of components and/or method steps set forth in the following description or illustrated in the drawings, and phraseology and terminology used herein is for the purpose of description and should not be regarded as limiting. The invention is capable of other embodiments and of being practiced or being carried out in various ways. Accordingly, other aspects, advantages, and modifications will be apparent to those skilled in the art to which the invention pertains, and these aspects and modifications are within the scope of the invention, which is limited only by the appended claims.

Optimizing modeled equations or systems of equations require techniques fundamentally to maximize, minimize, or optimize a real function to get desired results. Optimizing an equation or model requires a fundamental or basic mathematical model that describes and predicts the process response. The resultant optimized equations and models can be further scaled up to help real-world problems. But modeling a system requires deep understanding of the system and the art of modeling to get accurate, high-fidelity models. Control system strategies with time-variant, multiphase, or multi-dimensional reactors in a system for modeling and optimization are very complex.

Moreover, implementing these optimization methods is another complex aspect that requires a lot of skill, time and has a huge computation cost associated with it. For utilizing the optimized models in real-time and real-world situations optimization needs to be followed by machine learning providing reinforcement, supervised, and unsupervised solutions by different programmable computing devices using different methods. The modeled system should have an understanding of real situations affecting the dynamics of variables. Traditionally, these methods are good for single-dimensional, time-invariant, and bounded constraints or systems, furthermore, these methods use either gradient-based or gradient-free to solve both constrained and unconstrained optimization problems.

Traditionally, solving problems and conducting experiments are done on the basis of a mathematical equation like electrical current-voltage problems, kinematics of single or dual objects, or thermodynamics of gas particles under controlled conditions keeping other parameters ideal, that can be solved by differential equations.

But when problems like handling the gas particles at different temperatures, studying their state, with the kinematics or fluidity of the particles and different energy levels of valence electrons associated with it, and hence determining its industrial applications simultaneously are a big challenge. Further, maintaining high fidelity for imitating the experiments for other applications also requires high accuracy and a deep understanding of each of the fields involved in such Multiphysics problems. Implementing a realistic model derived from such Multiphysics problems on classical sluggish computers is an impractical approach as complexity rises exponentially in modeling such a problem as close as possible to reality. Traditional (e.g., classical) computers have less restricted active memory, processor, and rendering capabilities which are not sufficient, as continuous and simultaneous evaluation in each dimension reflects changes in the other dimension.

Therefore, there is a need in the art for a system and method that facilitates optimization by a means of computing that is more efficient and effective in comparison to the existing methods.

Furthermore, there is a need in the art for a system and method that facilitates solving high-fidelity Multiphysics problems using quantum technology.

Engineering problems such as, for example, non-linear, high dimensional, multi-objective problems present unique challenges to their solving via computer.

Conventional attempts at increasing efficiency and effectiveness of solving engineering problems include fast parallel computing. Fast parallel computing is a method where multiple processing units work concurrently to solve a computational problem more quickly than with a single unit. This technique exploits the inherent parallelism within tasks, breaking them into smaller sub-tasks that can be processed simultaneously. By distributing the computation load across multiple cores or even across separate machines in a cluster, parallel computing accelerates data processing, leading to quicker results. However, fast parallel computing still relies on classical computing hardware and limitations, including that power in a classical computer only increases linearly with the number of transistors.

An alternative hardware system is required to handle the complexity and parallelism without compromising the speed of the calculation.

Quantum computers provide advantages for complex tasks like optimization problems, data, analysis, and simulations. Quantum computer power grows exponentially with the number of quantum bits (“qubits”) in a system. Quantum computers can serve a large volume of data (e.g., multiphysics data) and can operate over it simultaneously so that high fidelity can be achieved for various studies and applications. Quantum computers may enable faster exploration of an entire design space compared to a localized design space from traditional optimization algorithms, thereby enabling use of larger design spaces.

Implementations herein may leverage quantum computing to provide accurate identification of global solutions, reduce the number of iterations (and therefore simulation time), and reduce compute resources (and thereby reducing cost of high-performance computing). Furthermore, quantum computing is inherently probabilistic, which means it solves challenges based on the most probable outcome while using several dimensions simultaneously.

Implementations may use quantum computing systems. A quantum computing system may include a quantum processing unit and a qubit support system.

The quantum processing unit (QPU) may employ superconducting quantum interfaces devices and may employ quantum transistors. A QPU may include a qubit support subsystem configured to support qubits. The qubit support subsystem may maintain qubits at low temperatures to enhance coherence (thereby diminishing decoherence) and minimize interference. The qubit support subsystem may maintain qubits in vacuum (e.g., near-vacuum) to reduce vibrations and promote balance of the qubits. A QPU may also include a classical computer configured to run programs and interface with and communicate input and output with the QPU.

The quantum computing system may leverage the collective properties of quantum states, such as superposition, interference, and entanglement, to perform calculations. The quantum computing system may thus employ these and other quantum physics principles to encode and manipulate information rather than relying upon classical models of computation.

Superposition holds that a quantum system, like a quantum bit (qubit), can exist simultaneously in multiple states. Instead of a classical bit, which is either in a 0 or 1 state, a qubit in superposition is in a linear combination of both 0 and 1 states until measured. When measuring the qubit, it can collapse to one of the base states (0 or 1) with certain probabilities. This simultaneous existence in multiple states allows quantum computers to process vast amounts of information in parallel, leading to their potential to solve certain problems much faster than classical computers.

Interference is rooted in the wave-like nature of qubits. Interference involves the combination of quantum states in such a way that they either amplify (constructive interference) or cancel each other out (destructive interference). In a quantum algorithm, qbits may be manipulated to make the incorrect solutions interfere destructively and cancel out, while the correct solutions interfere constructively and become more pronounced. This unique property allows quantum computers to sift through vast amounts of information more efficiently than classical computers in certain situations.

Entanglement is a quantum phenomenon where two or more particles become correlated in such a manner that the state of one particle is dependent on the state of the other, regardless of the distance between them. When entangled particles are measured, their outcomes are correlated in ways that classical physics cannot explain. For instance, if two entangled electrons are separated and the spin of one is measured along a particular axis, the spin of the other, when measured along the same axis, will be found to be in the opposite direction, instantaneously, even if they are light-years apart.

Decoherence refers to the process by which a quantum system loses its inherent quantum properties when interacting with an external environment. It's a primary obstacle in quantum computing because it causes a quantum system, such as a qubit, to lose its superposition state. Essentially, as a qubit interacts with its surroundings, it may tend to “leak” quantum information to the environment, causing it to behave more classically. This hinders an ability to maintain and manipulate quantum states in a controlled manner, thus presenting challenges in the development and scaling of quantum computers. Addressing decoherence is crucial for the practical realization of robust quantum computation.

For example, a quantum circuit can employ qubits that may be put in a superposition and/or entanglement state, based on principles of quantum physics. The superposition principle of quantum physics allows each qubit to represent both a value of “1” and a value of “0” at the same time (along with a complex-valued phase). Superposition means that each qubit can represent both a 1 and a 0 at the same time. Entanglement means that qubits in a superposition can be correlated with each other in a non-classical way and that there is more information that can be ascertained about the two qubits when they are entangled than when they are treated individually. Quantum computing can create various scenarios and run simulations based on pre-fed generalized data.

The qubits may be arranged so as to form one or more quantum logic gates, and thereby to arrange and compose quantum circuits. The quantum logic gate may be a Hadamard quantum logic gate, a rotational logic gate, a Pauli-X quantum logic gate, a Pauli-Y quantum logic gate, a Pauli-Z quantum logic gate, a phase quantum logic gate, a controlled-not quantum logic gate, a Swap quantum logic gate, a Toffoli quantum logic gate or a Deutsch logic gate.

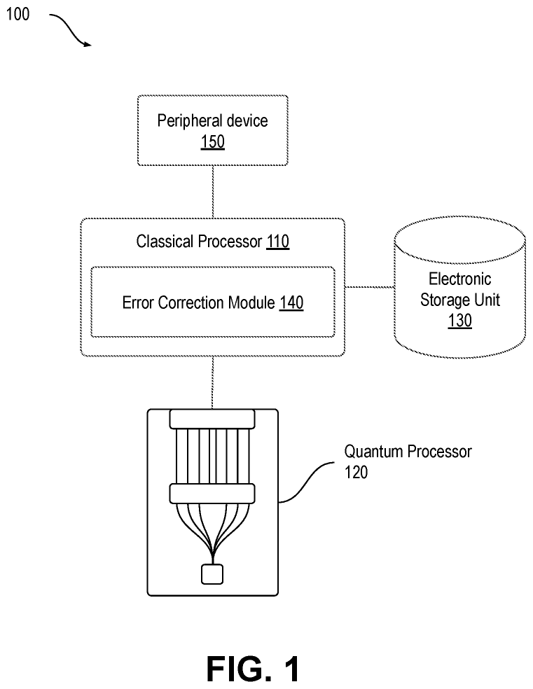

FIG. 1 illustrates a quantum computing system 100 for solving engineering problems using quantum computing, according to one or more implementations herein. Quantum computing system 100 may function to provide enhanced functionality of engineering problem solvers by enabling use of quantum algorithms.

The quantum computing system 100 may comprise a processor 110 configured for classical binary computing operation. The system 100 may comprise a quantum processor 120 configured for quantum computing operation. The quantum processor 120 may comprise a quantum bit. The quantum bit may be configured for superposition. The quantum bit may be configured for entailment. The quantum processor may comprise a quantum bit interface module. The quantum bit interface module may be configured to receive a quantum input from the processor 110. The quantum bit interface module may be configured to manipulate the quantum bit based on the quantum input. The quantum bit interface module may be configured to measure the quantum bit. The quantum bit interface module may be configured to determine a quantum output by measuring the quantum bit. The quantum bit interface module may be configured to output the measurement of the quantum bit to the processor 110. The quantum computing system 100 may include an electronic storage device 130. The electronic storage device 130 may be in communication with the processor 110. The electronic storage device may have an engineering model stored thereon. The engineering model may comprise a quantum algorithm.

A peripheral device 150 may be used to provide input to or output output from the processor 110 (e.g., user input or output).

Methods may include receiving, at the processor 110, an input for the engineering problem. The method may further include retrieving, using the processor 110, from the electronic storage device 130, the engineering model. The method may further include applying, using the processor 110, the input to the engineering model. The method may further include generating, using the processor 110, the quantum input based on the quantum algorithm. The method may further include communicating, using the processor 110, the quantum input to the quantum bit interface module of the quantum processor 120. The method may further include receiving, at the processor 110, the quantum output resulting from measuring the quantum bit from the quantum bit interface module of the quantum processor 120. The method may further include determining, using the processor 110, an output of the engineering model.

In some implementations, the engineering problem may comprise a multiphysics problem. The multiphysics problem may include a partial differential equation. The multiphysics problem may be configured for solving using a finite element method, a finite volume method, a finite difference method, a Boundary Element method, a spectral method, a meshless method, or a machine learning model. The multiphysics problem may comprise a fluid dynamics simulation problem, a structural mechanics simulation problem, a dynamics simulation problem, a heat transfer simulation problem, an acoustics simulation problem, an electromagnetic simulation problem, an electrochemistry simulation problem.

In some implementations, the engineering problem may comprise a design optimization problem, a topology optimization, a sizing optimization, a shape optimization. The design optimization problem may comprise one or more of a plurality of objectives or a plurality of constraints or a multidisciplinary optimization method. The design optimization problem may be configured for solving using a gradient-based optimization method, an evolutionary optimization method, or an annealing-based optimization method.

The design optimization problem may be configured for solving using a surrogate optimization method. Surrogate optimization involves using a surrogate model to approximate the objective function of an optimization problem. Instead of directly evaluating the costly or time-consuming objective function at every iteration, the surrogate model provides an estimate.

The surrogate optimization method may comprise a machine learning model (e.g., a neural network).

The design optimization problem may be configured for solving using a Design of Experiment method. The design optimization problem may be configured for solving using linear programming or non-linear programming. The design optimization problem may be configured for solving using a response surface method.

A graphic representation based on the output of the engineering model, such as tabular data, graphical data, image data, and the like. The graphic representation may be displayed on a display in electronic communication with the processor.

The method may further comprise determining, using an error correction module operating on the processor, An error of the engineering problem may be determined using an error correction module 140. Using error correction module 140 operating on the processor 110, an engineering model correction may be determined based on the error (e.g., based on minimizing the error). The engineering model correction may be applied to the engineering model to yield a corrected engineering model. Following, the input may be applied to the corrected engineering model; a corrected quantum input may be generated based on the quantum algorithm of the corrected engineering model; the corrected quantum input may be communicated to the quantum bit interface module of quantum processor 120; a corrected quantum output resulting from measuring the quantum bit may be received at processor 110; and a corrected output of the engineering model may be determined.

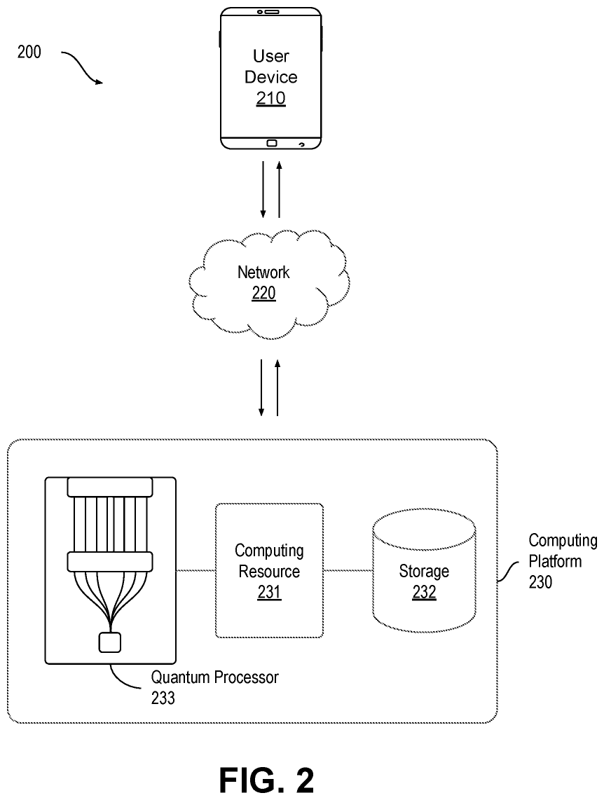

FIG. 2. Illustrates an operational environment 200 for one or more of the implementations herein. As illustrated in FIG. 2, environment 200 may include actors, including a user device 210, a network 220, an computing platform 230 having at least a computing resource 231 and a storage 232, and a quantum processor 233.

User device 210 may include any variety of devices a user may use to interface with computing platform 230 via network 220, including, for example, a server, a desktop computer, a laptop computer, a handheld computer, a tablet computing platform, a Netbook, a Smartphone, a gaming console, and/or other computing platforms.

Network 220 may include any variety of devices configured to enable a device communicate with other devices, such as via a wired connection and/or a wireless connection, for example, via the internet and/or other networks using, for example, TCP/IP or cellular hardware enabling wired or wireless (e.g., cellular, 2G, 3G, 4G, 4G LTE, 5G, or WiFi) communication. For example, network 220 may include, inter alia, a receiver, a transmitter, a transceiver, a modem, a network interface card, and/or an antenna.

Computing platform 230 may include any variety of devices configurable to perform the implementations and methods disclosed herein and interface with user device 210 via network 220, including, for example, a server, a desktop computer, a laptop computer, a handheld computer, a tablet computing platform, a Netbook, a Smartphone, a gaming console, and/or other computing platforms.

Computing platform 230 may include computing resource 231. Computing resource 231 may include, for example, one or more processor(s) configured to execute machine-readable instructions for implementing all or some of the implementations herein. Computing resource 231 may be configured to access storage 232 to retrieve and/or write electronic data from and to storage 232.

Computing platform 230 may include storage 232. Storage 232 may be configured to host one or more databases or other forms of data storage for use in implementations herein. Storage 232 may be accessible by computing resource 231.

Quantum processor 233 may include any variety of quantum computing devices that may interface with computing resource 231. Quantum processor 233 may comprise a quantum bit. The quantum bit may be configured for superposition. The quantum bit may be configured for entailment. Quantum processor 233 may comprise a quantum bit interface module. The quantum bit interface module may be configured to receive a quantum input from the processor. The quantum bit interface module may be configured to manipulate the quantum bit based on the quantum input (e.g., via electrical signals, electromagnetic signals, etc.). The quantum bit interface module may be configured to measure the quantum bit. The quantum bit interface module may be configured to determine a quantum output by measuring the quantum bit. The quantum bit interface module may be configured to output the measurement of the quantum bit to the computing resource 231. Quantum processor 233 may comprise a plurality of quantum bits including the quantum bit. Quantum processor 233 may comprise a quantum logic gate comprising the quantum bit. The quantum computing system may further comprise a graphics processing unit. The quantum computing system may further comprise a tensor processing unit. The quantum computing system may further comprise a field-programmable gate array. Computing resource 231, Quantum processor 233, and at least one of a graphics processing unit, a tensor processing unit, or a field-programmable gate array may be configured in a high-performance computing heterogeneous architecture. Quantum processor 233 may be an emulated quantum processor. Quantum processor 233 may be remote from the processor. Communicating the quantum input using the processor to the quantum bit interface module may be via a network (e.g., the internet). The quantum computing system may include a refrigeration system configured to maintain the quantum bit at a temperature below an ambient temperature of the quantum computing system. The quantum computing system may include a vacuum system configured to maintain the quantum bit in low vacuum, medium vacuum, high vacuum, ultra-high vacuum, or extreme-high vacuum.

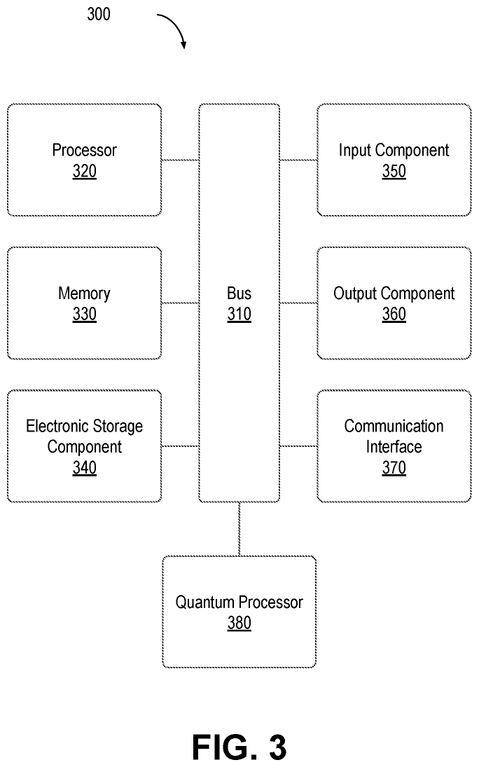

FIG. 3 is a diagram of example components of a device 300, which may correspond to one or more of the device(s), network(s), resource(s), or service(s) of FIG. 2. In some implementations, one or more of the device(s), network(s), resource(s), or service(s) of FIG. 2 may include one or more devices 300 and/or one or more components of device 300, for example, according to a client/server architecture, a peer-to-peer architecture, and/or other architectures, which may include a plurality of hardware, software, and/or firmware components operating together to provide the functionality attributed herein to device 300. In some implementations, device 300 may include a distributed computing architecture (e.g., one or more individual computing platforms operating in concert to accomplish a computing task). For example, device 300 may be implemented by a cloud of computing platforms operating together as device 300. By way of non-limiting example, a given device 300 may include one or more of a distributed computing platform, a cloud computing platform, a server, a desktop computer, a laptop computer, a handheld computer, a tablet computing platform, a Netbook, a Smartphone, a gaming console, and/or other computing platforms.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be used to implement the systems and/or methods based on the description herein.

As shown in FIG. 3, device 300 may include a bus 310, a processor 320, a memory 330, a storage component 340, an input component 350, an output component 360, a communication component 370, and a quantum processor 380.

Bus 310 includes a component that enables wired and/or wireless communication among the components of device 300.

Processor 320 includes a central processing unit, a graphics processing unit, a microprocessor, a controller, a microcontroller, a digital signal processor, a field-programmable gate array (FPGA), an application-specific integrated circuit, and/or another type of processing component. Processor 320 is implemented in hardware, firmware, or a combination of hardware and software. In some implementations, processor 320 includes one or more processors capable of being programmed to perform a function. Such processors may or may not be all integral to the same physical device, and may in some embodiments be distributed among several devices.

Processor 320 may be configured to execute one or more of the modules disclosed herein, and/or other modules by software; hardware; firmware; some combination of software, hardware, and/or firmware; and/or other mechanisms for configuring processing capabilities on processor 320. As used herein, the term “module” may refer to any component or set of components that perform the functionality attributed to the module. This may include one or more physical processors during execution of processor readable instructions, the processor readable instructions, circuitry, hardware, storage media, or any other components. Various modules or portions thereof may be implemented in any of various ways, including procedure-based techniques, component-based techniques, and/or object-oriented techniques, among others. For example, the program instructions may be implemented using system libraries, language libraries, model-view-controller (MVC) principles, application programming interfaces (APIs), system-specific programming languages and principles, cross-platform programming languages and principles, pre-compiled programming languages, markup programming languages, stylesheet languages, “bytecode” programming languages, object-oriented programming principles or languages, other programming principles or languages, C, C++, C#, Java, JavaScript, Python, PHP, HTML, CSS, TypeScript, R, Elm, Unity, VB.Net, Visual Basic, Swift, Objective-C, Perl, Ruby, Go, SQL, Haskell, Scala, Arduino, assembly language, Microsoft Foundation Classes (MFC), Streaming SIMD Extension (SSE), or other technologies or methodologies, as desired. Processor 300 may be configured to implement instructions in accordance with implementations herein stored upon tangible, non-transient, computer-readable media.

It should be appreciated that although some modules disclosed herein may be illustrated for example as being implemented within a single processing unit, in embodiments in which processor 320 includes multiple processing units, one or more of modules disclosed herein may be implemented remotely from the other modules. The description of the functionality provided by the different modules disclosed herein is for illustrative purposes, and is not intended to be limiting, as any of modules described herein may provide more or less functionality than is described. For example, one or more of modules disclosed herein may be eliminated, and some or all of its functionality may be provided by other ones of modules disclosed herein. As another example, processor 320 may be configured to execute one or more additional modules that may perform some or all of the functionality attributed herein to one of modules disclosed herein.

Memory 330 includes a random-access memory, a read only memory, and/or another type of memory (e.g., a flash memory, a magnetic memory, and/or an optical memory).

Electronic storage component 340 stores information and/or software related to the operation of device 300. For example, electronic storage component 340 may include a hard disk drive, a magnetic disk drive, an optical disk drive, a solid-state disk drive, a compact disc, a digital versatile disc, and/or another type of non-transitory computer-readable medium. Implementations of electronic storage component 340 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Implementations of electronic storage component 340 may include one or both of system storage provided integrally (i.e., substantially non-removable) to device 300 and/or removable storage that is removably connectable to device 300 via, for example, a port (e.g., a USB port, an IEEE 1394 port, a THUNDERBOLT™ port, etc.) or a drive (e.g., disk drive, flash drive, or solid-state drive etc.). Electronic storage component 340 may also or alternatively include one or more virtual storage resources (e.g., cloud storage, a virtual private network, and/or other virtual storage resources). An electronic storage may store software algorithms, information determined by one or more processors, information received from one or more computing platforms, information received from one or more remote platforms, databases (e.g., structured query language (SQL) databases (e.g., MYSQL®, MARIADB®, MONGODB®), NO-SQL databases, among others), data files, compiled data, analyzed data, charts, tables, videos, images, presentations, and 3D content in the respective format and/or other information enabling a computing platform to function as described herein.

Input component 350 enables device 300 to receive input, such as user input and/or sensed inputs. For example, input component 350 may include a touch screen, a keyboard, a keypad, a mouse, a button, a microphone, a switch, a sensor, a global positioning system component, an accelerometer, a gyroscope, and/or an actuator.

Output component 360 enables device 300 to provide output, such as via a display, a speaker, and/or one or more light-emitting diodes. For example, where output component 360 is a display, it may be configured to display images. Processor 320 may be directly or indirectly in operative electronic communication with output component 360. Output component 360 may include a device (or “hardware component”) that displays “display data” to form an image or images, such as, but not limited to, a picture, text, a desktop background, a gaming background, a video, an application window etc. One example of output component 360 may include an integrated display as found in electronic devices such as handheld computing devices, electronic book readers, mobile telephones (smartphones), personal-digital-assistants (PDAs), wearable devices (smart-watches, smart-glasses, etc.). Output component 360 may employ any appropriate display technology, such as for example, LCD flat panel, LED flat panel, flexible-panels, etc., and may include other display hardware that may, as needed for a particular electronic device, be operatively coupled to other devices and components. Therefore, output component 360 may include display hardware such as, but not limited to, a frame buffer, hardware display drivers, etc. that store and refresh display data to be displayed by output component 360. Also, output component 360 may include integrated hardware for implementation of touchscreen functionality such that the display is operative to receive user input by touch or via a stylus. The term “image” as used herein may refer generally to what is “displayed” on a display and which may be stored in memory as “display data.” That is, an image may be displayed on a display by sending the appropriate display data to the display. Examples of images may include, but are not limited to, an application window, an icon, a widget, tabular program output, graphical program output, etc. The term “display data” may be used interchangeably herein with the term “image data” and refers to the information (data, or digital information) that the display interprets and/or decodes to show (i.e., to display) the user an image, as well as any associated elements or objects.

Communication component 370 enables device 300 to communicate with other devices, such as via a wired connection and/or a wireless connection, for example, via the internet and/or other networks using, for example, TCP/IP or cellular hardware enabling wired or wireless (e.g., cellular, 2G, 3G, 4G, 4G LTE, 5G, or WiFi) communication. For example, communication component 370 may include a receiver, a transmitter, a transceiver, a modem, a network interface card, and/or an antenna.

As used herein, “internet” may include an interconnected network of systems and a suite of protocols for the end-to-end transfer of data therebetween. A model describing may be the Transport Control Protocol and Internet Protocol (TCP/IP), which may also be referred to as the internet protocol suite. TCP/IP provides a model of four layers of abstraction: an application layer, a transport layer, an internet layer, and a link layer. The link layer may include hosts accessible without traversing a router, and thus may be determined by the configuration of the network (e.g., a hardware network implementation, a local area network, a virtual private network, or a networking tunnel). The link layer may be used to move packets of data between the internet layer interfaces of different hosts on the same link. The link layer may interface with hardware for end-to-end transmission of data. The internet layer may include the exchange of datagrams across network boundaries (e.g., from a source network to a destination network), which may be referred to as routing, and is performed using host addressing and identification over an internet protocol (IP) addressing system (e.g., IPv4, IPv6). A datagram may include a self-contained, independent, basic unit of data, including a header (e.g., including a source address, a destination address, and a type) and a payload (e.g., the data to be transported), to be transferred across a packet-switched network. The transport layer may utilize the user datagram protocol (UDP) to provide for basic data channels (e.g., via network ports) usable by applications for data exchange by establishing end-to-end, host-to-host connectivity independent of any underlying network or structure of user data. The application layer may include various user and support protocols used by applications users may use to create and exchange data, utilize services, or provide services over network connections established by the lower layers, including, for example, routing protocols, the hypertext transfer protocol (HTTP), the file transfer protocol (FTP), the simple mail transfer protocol (SMTP), and the dynamic host configuration protocol (DHCP). Such data creation and exchange in the application layer may utilize, for example, a client-server model or a peer-to-peer networking model. Data from the application layer may be encapsulated into UDP datagrams or TCP streams for interfacing with the transport layer, which may then effectuate data transfer via the lower layers.

Quantum processor 380 may be similar to quantum processor 233 or quantum processor 120 or as otherwise described herein, and may be in operative communication with processor 320, bus 310, or another component of system 300 directly or indirectly.

Device 300 may perform one or more processes described herein. For example, a non-transitory computer-readable medium (e.g., memory 330 and/or storage component 340) may store a set of instructions (e.g., one or more instructions, code, software code, and/or program code) for execution by processor 320. Processor 320 may execute the set of instructions to perform one or more processes described herein. In some implementations, execution of the set of instructions, by one or more processors 320, causes the one or more processors 320 and/or the device 300 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 3 are provided as an example. Device 300 may include additional components, fewer components, different components, or differently arranged components than those shown in FIG. 3. Additionally, or alternatively, a set of components (e.g., one or more components) of device 300 may perform one or more functions described as being performed by another set of components of device 300.

In addition to the example configuration described herein in FIG. 3, various steps, functions, and/or operations of device 300 and the methods disclosed herein may be carried out by one or more of, for example, electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link.

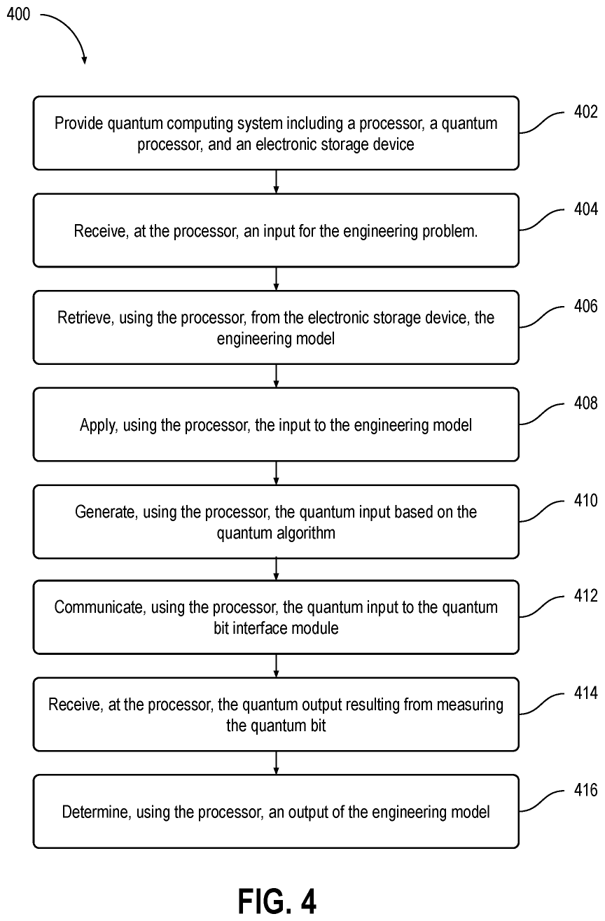

FIG. 4 is a flowchart illustrating an example method 400 for solving an engineering problem, according to one or more implementations herein. In some implementations, one or more operations illustrated in FIG. 4 may be performed by one or more devices of FIGS. 1-3, or one or more other devices. One or more of the operations of method 400 may be performed by one or more hardware processors configured by machine-readable instructions including a module in accordance with one or more embodiments.

An operation 402 may include providing a quantum computing system, and may be performed alone or in combination with one or more other operations depicted in FIG. 4. The quantum computing system may comprise a processor configured for classical binary computing operation. The system may comprise a quantum processor configured for quantum computing operation. The quantum processor may comprise a quantum bit. The quantum bit may be configured for superposition. The quantum bit may be configured for entailment. The quantum processor may comprise a quantum bit interface module. The quantum bit interface module may be configured to receive a quantum input from the processor. The quantum bit interface module may be configured to manipulate the quantum bit based on the quantum input. The quantum bit interface module may be configured to measure the quantum bit. The quantum bit interface module may be configured to determine a quantum output by measuring the quantum bit. The quantum bit interface module may be configured to output the measurement of the quantum bit to the processor. The quantum computing system may include an electronic storage device. The electronic storage device may be in communication with the processor. The electronic storage device may have an engineering model stored thereon. The engineering model may comprise a quantum algorithm.

An operation 404 may include receiving, at the processor, an input for the engineering problem, and may be performed alone or in combination with one or more other operations depicted in FIG. 4.

An operation 406 may include retrieving, using the processor, from the electronic storage device, the engineering model, and may be performed alone or in combination with one or more other operations depicted in FIG. 4.

An operation 408 may include applying, using the processor, the input to the engineering model, and may be performed alone or in combination with one or more other operations depicted in FIG. 4.

An operation 410 may include generating, using the processor, the quantum input based on the quantum algorithm, and may be performed alone or in combination with one or more other operations depicted in FIG. 4.

An operation 412 may include communicating, using the processor, the quantum input to the quantum bit interface module, and may be performed alone or in combination with one or more other operations depicted in FIG. 4.

An operation 414 may include receiving, at the processor, the quantum output resulting from measuring the quantum bit, and may be performed alone or in combination with one or more other operations depicted in FIG. 4.

An operation 416 may include determining, using the processor, an output of the engineering model, and may be performed alone or in combination with one or more other operations depicted in FIG. 4.

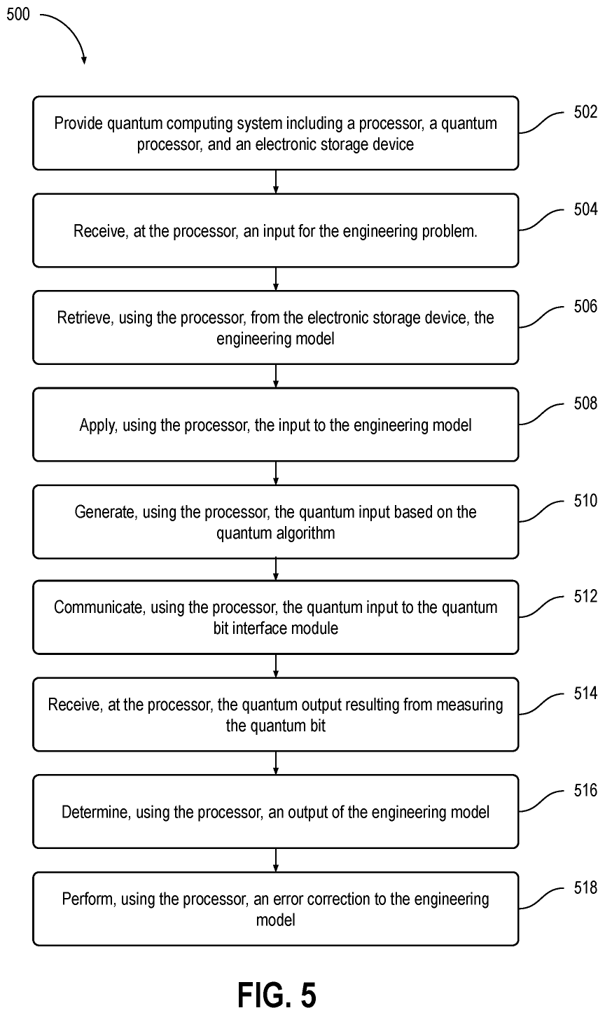

FIG. 5 is a flowchart illustrating an example method 500 for solving an engineering problem and determining an error correction, according to one or more implementations herein. In some implementations, one or more operations illustrated in FIG. 5 may be performed by one or more devices of FIGS. 1-3, or one or more other devices. One or more of the operations of method 500 may be performed by one or more hardware processors configured by machine-readable instructions including a module in accordance with one or more embodiments.

An operation 502 may include providing a quantum computing system, and may be performed alone or in combination with one or more other operations depicted in FIG. 5. The quantum computing system may comprise a processor configured for classical binary computing operation. The system may comprise a quantum processor configured for quantum computing operation. The quantum processor may comprise a quantum bit. The quantum bit may be configured for superposition. The quantum bit may be configured for entailment. The quantum processor may comprise a quantum bit interface module. The quantum bit interface module may be configured to receive a quantum input from the processor. The quantum bit interface module may be configured to manipulate the quantum bit based on the quantum input. The quantum bit interface module may be configured to measure the quantum bit. The quantum bit interface module may be configured to determine a quantum output by measuring the quantum bit. The quantum bit interface module may be configured to output the measurement of the quantum bit to the processor. The quantum computing system may include an electronic storage device. The electronic storage device may be in communication with the processor. The electronic storage device may have an engineering model stored thereon. The engineering model may comprise a quantum algorithm.

An operation 504 may include receiving, at the processor, an input for the engineering problem, and may be performed alone or in combination with one or more other operations depicted in FIG. 5.

An operation 506 may include retrieving, using the processor, from the electronic storage device, the engineering model, and may be performed alone or in combination with one or more other operations depicted in FIG. 5.

An operation 508 may include applying, using the processor, the input to the engineering model, and may be performed alone or in combination with one or more other operations depicted in FIG. 5.

An operation 510 may include generating, using the processor, the quantum input based on the quantum algorithm, and may be performed alone or in combination with one or more other operations depicted in FIG. 5.

An operation 512 may include communicating, using the processor, the quantum input to the quantum bit interface module, and may be performed alone or in combination with one or more other operations depicted in FIG. 5.

An operation 514 may include receiving, at the processor, the quantum output resulting from measuring the quantum bit, and may be performed alone or in combination with one or more other operations depicted in FIG. 5.

An operation 516 may include determining, using the processor, an output of the engineering model, and may be performed alone or in combination with one or more other operations depicted in FIG. 5.

An operation 518 may include performing, using the processor, an error correction to the engineering model, and may be performed alone or in combination with one or more other operations depicted in FIG. 5. The error correction operation may comprise: determining, using an error correction module operating on the processor, an error; determining, using the error correction module operating on the processor an engineering model correction based on the error, and applying, using the processor, the engineering model correction to the engineering model to yield a corrected engineering model. Determining the engineering model correction may be based on minimizing the error.

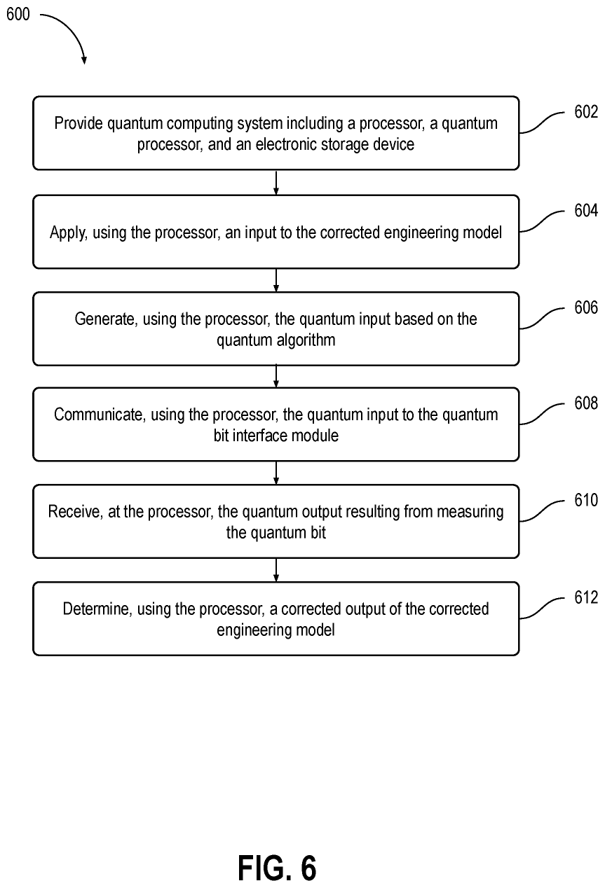

FIG. 6 is a flowchart illustrating an example method 600 for solving an engineering problem with error correction applied, according to one or more implementations herein. In some implementations, one or more operations illustrated in FIG. 6 may be performed by one or more devices of FIGS. 1-3, or one or more other devices. One or more of the operations of method 600 may be performed by one or more hardware processors configured by machine-readable instructions including a module in accordance with one or more embodiments.

An operation 602 may include providing a quantum computing system, and may be performed alone or in combination with one or more other operations depicted in FIG. 6.

An operation 604 may include applying, using the processor, an input a corrected engineering model, and may be performed alone or in combination with one or more other operations depicted in FIG. 6.

An operation 606 may include generating, using the processor, the quantum input based on the quantum algorithm, and may be performed alone or in combination with one or more other operations depicted in FIG. 6.

An operation 608 may include communicating, using the processor, the quantum input to the quantum bit interface module, and may be performed alone or in combination with one or more other operations depicted in FIG. 6.

An operation 610 may include receiving, at the processor, the quantum output resulting from measuring the quantum bit, and may be performed alone or in combination with one or more other operations depicted in FIG. 6.

An operation 612 may include determining, using the processor, a corrected output of the corrected engineering model, and may be performed alone or in combination with one or more other operations depicted in FIG. 6.

In some embodiments, at least some portions of the methods illustrated in FIGS. 4-6 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of the methods illustrated in FIGS. 4-6 in response to instructions stored electronically on an electronic storage medium. The one or more processing devices may include one or more devices configured through hardware, firmware, and/or software to be specifically designed for execution of one or more of the operations of methods illustrated in FIGS. 4-6.

Although FIGS. 4-6 depict example methods 400-600, respectively, and operations thereof, in some implementations, a method illustrated herein may include additional operations, fewer operations, differently arranged operations, or different operations than the operations depicted in FIGS. 4-6. Moreover, or in the alternative, two or more of the operations depicted in FIGS. 4-6 may be performed at least partially in parallel.

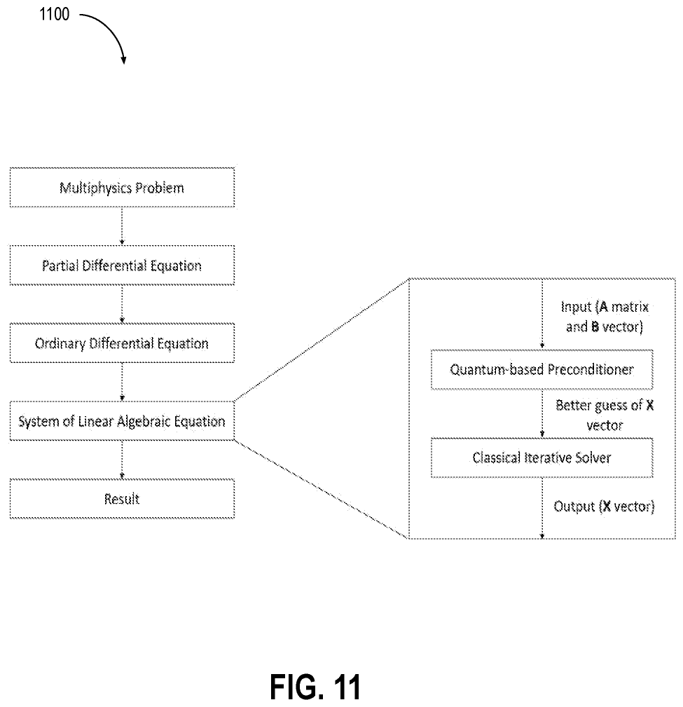

FIG. 11 may illustrate an example solution process 1100 of a multiphysics problem, according to one or more implementations herein. Process 1100 may be applied to, for example, solving for HVAC systems in an electric vehicle.

In accordance with an example embodiment of the present disclosure, a system for solving high-fidelity Multiphysics problems using quantum computing, these models may be used for design and analysis of Heating, ventilation, and air conditioning (HVAC) systems in an electric car.

With the advent of electric cars, the HVAC system has become a challenging area as it requires a robust Multiphysics analysis using simulations. Each component of the HVAC system (e.g., air conditioning systems, fans, and blowers), can be modeled as independent multiphysics problems, such as, for example, fluid dynamics, structural mechanics, heat transfer, acoustics, electromagnetic, and electrochemistry. Each Multiphysics problem can be studied/explained using a partial differential equation (PDE) and solved using existing methods such as finite element/volume/difference method. Due to the computational complexity, these PDEs can take immense amounts of time to be solved. To speed up these simulations, the present disclosure provides a novel approach of solving highly precise models using Quantum Technologies with a performance increase.

Embodiments of the present disclosure provide a quantum technology-based system for solving high-fidelity Multiphysics problems (hereinafter referred to as “the system”). The system for solving high-fidelity Multiphysics problems using quantum technology comprises one or more processing modules with reversible gates, storage, and a quantum error correction module. The processing module and the storage are based on quantum technology wherein quantum technology use Qubits not bits or bytes as traditional computing devices.

The processing module is responsible for computing or arithmetic and logical operations while the first storage unit is related to the storage of prior data sets and solutions and transitional data used in the process. The processing module, the storage, and the error correction module are operably connected to each other. The processing module supports superposition and entailment properties. The processing module may be further operably connected with, but is not limited to, one or more second processing modules through an interface. The one or more second processing modules are proximal to second storage which are further connected to one or more peripherals. The peripheral can be one or more input and output devices from which a user can interact with the system.

The method can handle the complexity but the speed of the calculation can be increased by using the technologies like quantum computing which can handle a large volume of data and can operate over it simultaneously.

Implementations may implement machine learning, a type of artificial intelligence (AI) that provides computers with an ability to learn how to process data without being explicitly programmed. Machine learning focuses on the development of computer programs that can teach themselves to grow and change when exposed to new data. Machine learning explores the study and construction of algorithms that can learn from and make predictions based on data. Such algorithms may overcome following strictly static program instructions by making data-driven predictions or decisions, through building a model from sample inputs.

Machine learning may refer to a variety of AI software algorithms, which may be used to perform supervised learning, unsupervised learning, reinforcement learning, deep learning, or any combination thereof. A variety of different machine learning algorithms may be employed in implementations. Examples of machine learning algorithms may include, inter alia, artificial neural network algorithms, Gaussian process regression algorithms, fuzzy logic-based algorithms, or decision tree algorithms.

In some implementations, more than one machine learning algorithm may be employed. For example, automated classification may be implemented using one type of machine learning algorithm, and adaptive real-time process control may be implemented using a different type of machine learning algorithm. In some implementations, hybrid machine learning algorithms including features and properties drawn from two, three, four, five, or more different types of machine learning algorithms may be employed in implementations.

Supervised learning algorithms may use labeled training data to infer a relationship between one or more identifiable aspects of a given entity and a classification of the entity according to a specified set of criteria or to infer a relationship between input process control parameters and desired outcomes. The training data may include paired training examples. For example, each training data example may include aspects identified for a given entity and the resultant classification of the given entity. As a further example, each training data example may include process control parameters used in a process and a known outcome of the process.

Unsupervised learning algorithms may be used to draw inferences from training data including entity data not paired with labeled entity classification data, or input process control parameter data not paired with labeled process outcomes. An example unsupervised learning algorithm is cluster analysis, which may be used for exploratory data analysis to find hidden patterns or groupings in process data.

Semi-supervised learning algorithms may use both labeled and unlabeled object classification or process data for training. Semi-supervised learning algorithms may typically use a small amount of labeled data with a large amount of unlabeled data.

Reinforcement learning algorithms may be used, for example, to optimize a process (e.g., steps or actions of the process) to maximize a process reward function or minimize a process loss function. In machine learning environments, reinforcement learning algorithms may be formulated as Markov decision processes. Reward functions or loss functions, which may also be referred to as cost functions or error functions, may map values of one or more process variables and/or outcomes to a real number that represents a reward or cost, respectively, associated with a given process outcome or event. Examples of process parameters and process outcomes include, inter alia, process throughput, process yield, production quality, or production cost. In some cases, the definition of the reward or loss function to be maximized or minimized, respectively, may depend on the choice of machine learning algorithm used to run the process control method, or vice versa. For example, if an objective is to maximize a total reward/value function, a reinforcement learning algorithm may be chosen. If the objective is to minimize a mean squared error loss function, a decision tree regression algorithm or linear regression algorithm may be chosen. In general, the machine learning algorithm used to run the process control method will seek to optimize the reward function or minimize the loss function by identifying the current state of the process; comparing the current state to the reference state, which may be a target intermediate or final state; and adjusting one or more process control parameters to minimize a difference between the two states. This adjustment may include reference to past learning provided by a training data set. Reinforcement learning algorithms differ from supervised learning algorithms in that correct training data input/output pairs are not presented, nor are sub-optimal actions explicitly corrected. Implementations of these algorithms tend to focus on real-time performance by finding a balance between exploration of possible outcomes based on updated input data and exploitation of past training.

Deep learning, which may also be known as deep structured learning, hierarchical learning, or deep machine learning, may be based on a set of algorithms that attempt to model high level abstractions in data. Deep learning algorithms may be inspired by the structure and function of the human brain and are part of a broader family of machine learning methods based on learning representations of data. Rooted in neural network technology, deep learning may involve a probabilistic graph model having many neuron layers, commonly known as a deep architecture. Deep learning technology may process information such as, inter alia, image, text, or sound information in a hierarchical manner. An observation (e.g., a feature to be extracted for reference) can be represented in many ways including, for example, a vector of intensity values, a set of edges, regions of shape, or in another abstract manner. Some representations may simplify the learning task (e.g., face recognition or facial expression recognition). Deep learning can provide efficient algorithms for unsupervised or semi-supervised feature learning and hierarchical feature extraction. implementations employing deep learning can further benefit from the advantage of deep learning concepts in solving a normally intractable representation inversion problem.

A deep learning module may be configured as a neural network. The deep learning module may further be a deep neural network with a set of weights that model the world based on training using training data. Neural networks can be understood to implement a computational approach—based on a relatively large collection of neural units—to loosely model the way a human brain solves problems with large clusters of biological neurons connected by axons. Each neural unit may be connected to one or more others, and links can be enforcing or inhibitory in their effect on the activation state of connected neural units. These systems may be self-learning and trained rather than explicitly programmed. Neural network systems excel in areas where a solution or feature detection is difficult to express in a traditional computer program.

An example of a deep learning algorithm may be an artificial neural network (ANN). Large ANNs including many layers may be used, for example, to map entity data to entity classification decisions or to map input process control parameters to desired process outcomes. ANNs will be discussed in further detail below.

Neural networks typically include multiple layers, and the signal path may traverse from front to back. The goal of neural networks may be to solve problems in a similar manner to the human brain, although several neural networks may be much more abstract. In a simple example of a neural network, there may be two layers (i.e., sets) of neurons: an input layer that receives an input signal and an output layer that sends an output signal. When the input layer receives an input, it may pass a modified version of the input to the next layer. In a deep network, there may be many layers between the input layer and output layer, allowing the algorithm to use multiple processing layers, which may include multiple linear and non-linear transformations. Modern neural networks typically work with a few thousand to a few million neural units and millions of connections. Neural networks may have various suitable architectures and/or configurations known in the art.

There are many variants of neural networks with deep architecture depending on the probability specification and network architecture, including, inter alia, deep belief networks (DBN), restricted Boltzmann machines (RBM), random forests, and autoencoders. Implementations of neural networks may vary depending on the size of input data, the number of features to be analyzed, and the nature of the problem. Other layers may be included in the deep learning module besides the neural networks disclosed herein.

Another type of deep neural network may be a convolutional neural network (CNN), which can be used for analysis of an entity or process. CNNs are commonly composed of layers of different types: convolution, pooling, upscaling, and fully connected layers. In some cases, an activation function such as a rectified linear unit (ReLU) function may be used in some of the layers. In a CNN architecture, there can be one or more layers for each type of operation performed. A CNN architecture may include any number of layers in total, and any number of layers for the different types of operations performed. The simplest CNN architecture starts with an input layer followed by a sequence of convolutional layers and pooling layers (e.g., layers otherwise configured for reducing the dimensionality of the feature map generated by the one or more convolutional layers while retaining the most important features, for example, max pooling layers) and ends with fully connected layers (e.g., a layer in which each of the nodes is connected to each of the nodes in the previous layer).

Each convolution layer may include a plurality of parameters used for performing the convolution operations. Each convolution layer may also include one or more filters, which in turn may include one or more weighting factors or other adjustable parameters. In some instances, the parameters may include biases (e.g., parameters that permit an activation function to be shifted). In some cases, the convolutional layers may be followed by an ReLU activation function layer. Other activation functions can also be used, for example, inter alia, saturating hyperbolic tangent, identity, binary step, logistic, arctan, softsign, parametric rectified linear unit, exponential linear unit, softPlus, bent identity, softExponential, Sinusoid, Sinc, Gaussian, or sigmoid functions. The convolutional, pooling and ReLU layers may function as learnable feature extractors, while the fully connected layers may function as machine learning classifiers. As with other artificial neural networks, the convolutional layers and fully connected layers of CNN architectures may include various computational parameters, for example, weights, bias values, and threshold values, which may be trained in a training phase.

Another type of deep neural network may be a visual geometry group (VGG) network. For example, VGG networks may be created by increasing the number of convolutional layers while fixing other parameters of the architecture. Adding convolutional layers to increase depth may be made possible by using substantially small convolutional filters in all of the layers. VGG networks may also include convolutional layers followed by fully connected layers.

Another type of deep neural network may be a deep residual network. Like some other networks described herein, a deep residual network may include convolutional layers followed by fully connected layers, which may be, in combination, configured and trained for feature property extraction. A deep residual network's layers may be configured to learn residual functions with reference to layer inputs, instead of learning unreferenced functions. Instead of relying on a direct fit of few stacked layers to a desired underlying mapping, a deep residual network's layers may be explicitly allowed to fit a residual mapping, which may be realized by feedforward neural networks having shortcut connections (i.e., connections that skip one or more layers). A deep residual network may be created by inserting shortcut connections into a plain neural network structure including convolutional layers, thereby modifying the plain neural network into a residual learning network.

In some implementations, the machine learning module may include a support vector machine (SVM), an artificial neural network (ANN), a decision tree-based expert learning system, an autoencoder, a clustering machine learning algorithm, or a nearest neighbor (e.g., kNN) machine learning algorithm, or combinations thereof, some of which will be described in further detail below.

Support vector machines (SVMs) may be supervised learning algorithms used for classification and regression analysis of entity classification data or process control. Given a set of training data examples (e.g., entity or process data), each marked as belonging to a category, an SVM training algorithm may build a model that assigns new examples (e.g., data from a new entity or process) to a given category.

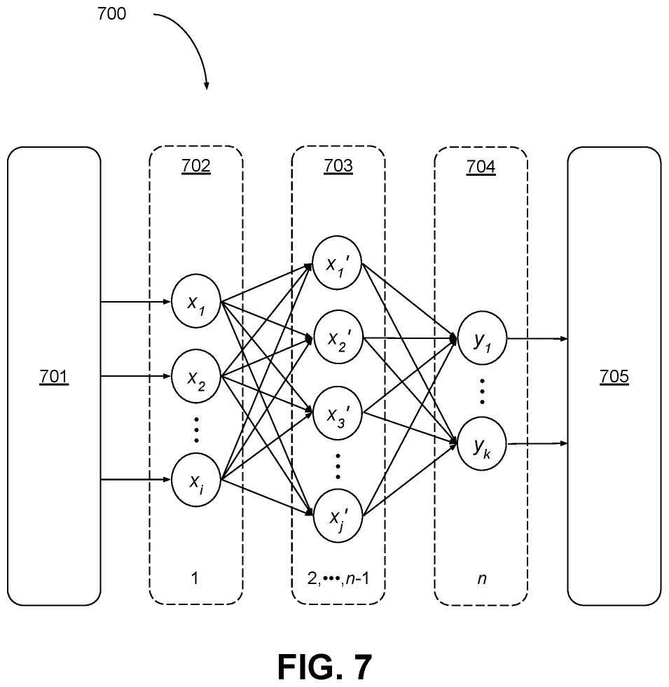

FIG. 7 illustrates an artificial neural network (ANN) 700, according to an implementation. ANN 700 may be used for, inter alia, classification or process control optimization according to various implementations.

ANN 700 may include any type of neural network module, such as, inter alia, a feedforward neural network, radial basis function network, recurrent neural network, or convolutional neural network.

In implementations implementing ANN 700 for entity classification, ANN 700 may be employed to map entity data to entity classification data. In implementations implementing ANN 700 for process optimization, ANN 700 may be employed to determine an optimal set or sequence of process control parameter settings for adaptive control of a process in real-time based on a stream of process monitoring data and/or entity classification data provided by, for example, observation or from one or more sensors. ANN 700 may include an untrained ANN, a trained ANN, pre-trained ANN, a continuously updated ANN (e.g., an ANN utilizing training data that is continuously updated with real time classification data or process control and monitoring data from a single local system, from a plurality of local systems, or from a plurality of geographically distributed systems).

ANN 700 may include interconnected nodes (e.g., x₁-xᵢ, x₁′-xⱼ′, and y₁-yₖ) organized into n layers of nodes, where x₁-xᵢ represents a group of i nodes in an input layer 702 (e.g., layer 1), x₁′-xⱼ′ represents a group of j nodes in one or more hidden layers 703 (e.g., layer(s) 2 through n-1), and y₁-yₖ represents a group of k nodes in a final layer 704 (e.g., layer n). Input layer 702 may be configured to receive input data 701 (e.g., sensor data, image data, sound data, observed data, automatically retrieved data, manually input data, etc.). Final layer 704 may be configured to provide result data 705.

There may be one or more hidden layers 703, and the number j of nodes in the one or more hidden layers 703 may vary from implementation to implementation. Thus, ANN 700 may include any total number of layers (e.g., the one or more hidden layers 703). One or more of the hidden layers 703 may function as trainable feature extractors, which may allow mapping of input data 701 to preferred result data 705.

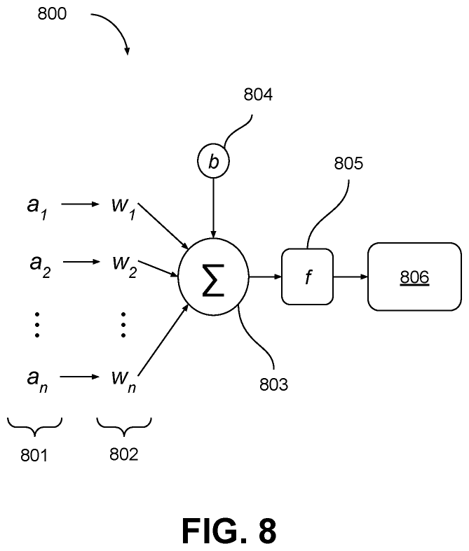

FIG. 8 illustrates a node 800, according to an implementation. Each layer of a neural network may include one or more nodes similar to node 800, for example, nodes x₁-xᵢ, x₁′-xⱼ′, and y₁-yₖ depicted in FIG. 7. Each node may be analogous to a biological neuron.

Node 800 may receive node inputs 801 (e.g., a₁-aₙ) either directly from the ANN's input data (e.g., input data 701) or from the output of one or more nodes in a different layer or the same layer. With node inputs 801, the node 800 may perform an operation 803, which while depicted in FIG. 8 as a summation operation, would be readily understood to include various other operations known in the art.

In some cases, node inputs 801 may be associated with one or more weights 802 (e.g., w₁-wₙ), which may represent weighting factors. For example, operation 803 may sum the products of each of node inputs 801 and associated weights 802 (e.g., aᵢwᵢ).

The result of operation 803 may be offset with one or more biases 804 (e.g., bias b), which may be a value or a function.

Output 806 of node 800 may be gated using an activation (or threshold) function 805 (e.g., function f), which may be a linear or a nonlinear function. Activation function 805 may be, for example, a ReLU activation function or other function such as a saturating hyperbolic tangent, identity, binary step, logistic, arctan, softsign, parametric rectified linear unit, exponential linear unit, softPlus, bent identity, softExponential, Sinusoid, Sinc, Gaussian, or sigmoid function, or any combination thereof.

Weights 802, biases 804, or threshold values of activation function 805, or other computational parameters of the neural network, can be “taught” or “learned” in a training phase using one or more sets of training data. For example, the parameters may be trained using input data from a training data set and a gradient descent or backward propagation method so that the output value(s) (e.g., a set of predicted adjustments to classification or process control parameter settings) computed by the ANN may be consistent with the examples included in the training data set. The parameters may be obtained, for example, from a back propagation neural network training process, which may or may not be performed using the same hardware as that used for automated classification or adaptive, real-time deposition process control.

Decision tree-based expert systems may be supervised learning algorithms designed to solve entity classification problems or process control problems by applying a series of conditional (e.g., if-then) rules. Expert systems may include two subsystems: an inference engine and a knowledge base. The knowledge base may include a set of facts (e.g., a training data set including entity data for a series of entities, and the associated entity classification data provided by, for example, a skilled operator, technician, or inspector) and derived rules (e.g., derived entity classification rules). The inference engine may then apply the rules to input data for a current entity classification problem or process control problem to determine a classification of the entity or a next set of process control adjustments.

Autoencoders (also sometimes referred to as an auto-associator or Diabolo network), may be an ANN used for unsupervised and efficient mapping of input data (e.g., entity data or process data), to an output value (e.g., an entity classification or optimized process control parameters). Autoencoders may be used for the purpose of dimensionality reduction, that is, a process of reducing the number of random variables under consideration by deducing a set of principal component variables. Dimensionality reduction may be performed, for example, for the purpose of feature selection (e.g., selecting a subset of the original variables) or feature extraction (e.g., transforming of data in a high-dimensional space to a space of fewer dimensions).

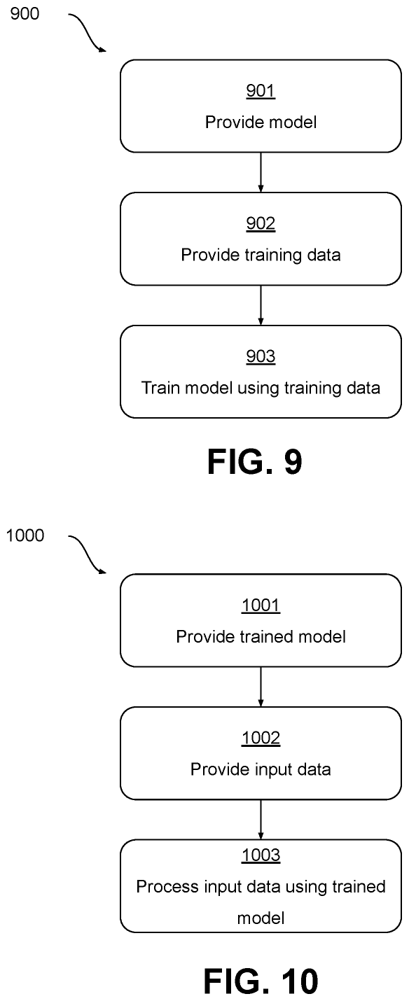

FIG. 9 illustrates a method 900 of training a machine learning model of a machine learning module, according to an implementation. Use of method 900 may provide for use of training data to train a machine learning model for concurrent or later use.

At 901, a machine learning model including one or more machine learning algorithms may be provided.

At 902, training data may be provided. Training data may include one or more of process simulation data, process characterization data, in-process or post-process inspection data (including inspection data provided by a skilled operator and/or inspection data provided by any of a variety of automated inspection tools), or any combination thereof, for past processes that are the same as or different from that of the current process. One or more sets of training data may be used to train the machine learning algorithm used for object defect detection and classification. In some cases, the type of data included in the training data set may vary depending on the specific type of machine learning algorithm employed.

At 903, the machine learning model may be trained using the training data. For example, training the model may include inputting the training data to the machine learning model and modifying one or more parameters of the model until the output of the model is the same as (or substantially the same as) external validation data. Model training may generate one or more trained models. One or more trained models may be selected for further validation or deployment, which may be performed using validation data. The results produced by each trained model for the validation data input to the training model may be compared to the validation data to determine which of the models is the best model. For example, the trained model that produces results most closely matching the validation data may be selected as the best model. Test data may then be used to evaluate the selected model. The selected model may also be sent to model deployment in which the best model may be sent to the processor for use in a post-training mode.

FIG. 10 illustrates a method 1000 of analyzing input data using a machine learning module, according to an implementation. Use of the machine learning module described by method 1000 may enable, for example, automatic classification of an entity or optimized process control.

At 1001, a trained machine learning model may be provided to the machine learning module. The trained machine learning model may have been trained, or under continuous or periodic training by one or more other systems or methods. The machine learning model may be pre-generated and trained, enabling functionality of the module as described herein, which can then be used to perform one or more post-training functions of the machine learning module.

For example, the provided trained machine learning model may be similar to ANN 700, include nodes similar to node 800, and may have been trained (or be under continuous or periodic training) using a method similar to method 900.

At 1002, input data may be provided to the machine learning module for input into the machine learning model. The input data may result from or be derived from a variety of different sources, similar to input data 701.

The provision of input data at 1002 may further include removing noise from the data prior to providing it to the machine learning algorithm. Examples of data processing algorithms suitable for use in removing noise from the input data may include, inter alia, signal averaging algorithms, smoothing filter algorithms, Kalman filter algorithms, nonlinear filter algorithms, total variation minimization algorithms, or any combination thereof.

The provision of input data at 1002 may further include subtraction of a reference data set from the input data to increase contrast between aspects of interest of an entity or process and those not of interest, thereby facilitating classification or process control optimization. For example, a reference data set may include input data for a real or contrived ideal example of the entity or process. If an image sensor or machine vision system is used for entity observation, the reference data set may include an image or set of images (e.g., representing different views) of an ideal entity.

At 1003, the machine learning module may process the input data using the trained machine learning model to yield results from the machine learning module. Such results may include, for example, an entity classification or one or more optimized process control parameters.

The following statements may provide additional context for the present disclosure but should be taken in no way as limiting.

Statement 1. A method for solving an engineering problem using quantum computing, comprising: providing a quantum computing system including: a processor configured for classical binary computing operation; a quantum processor configured for quantum computing operation, comprising: a quantum bit configured for superposition and entailment; and a quantum bit interface module configured to receive a quantum input from the processor, manipulate the quantum bit based on the quantum input, determine an quantum output by measuring the quantum bit, and output the measurement of the quantum bit to the processor; and an electronic storage device in electronic communication with the processor having an engineering model stored thereon, wherein the engineering model comprises a quantum algorithm; receiving, at the processor, an input for the engineering problem; retrieving, using the processor, from the electronic storage device, the engineering model; applying, using the processor, the input to the engineering model; generating, using the processor, the quantum input based on the quantum algorithm; communicating, using the processor, the quantum input to the quantum bit interface module; receiving, at the processor, the quantum output resulting from measuring the quantum bit; and determining, using the processor, an output of the engineering model.

Statement 2. The method of statement 1, wherein the engineering problem comprises a multiphysics problem.

Statement 3. The method of statement 2, wherein the multiphysics problem includes a partial differential equation.

Statement 4. The method of statement 2, wherein the multiphysics problem is configured for solving using a finite element method.

Statement 5. The method of statement 2, wherein the multiphysics problem is configured for solving using a finite volume method.

Statement 6. The method of statement 2, wherein the multiphysics problem is configured for solving using a finite difference method.

Statement 7. The method of statement 2, wherein the multiphysics problem is configured for solving using a Boundary Element method.

Statement 8. The method of statement 2, wherein the multiphysics problem is configured for solving using a spectral method.

Statement 9. The method of statement 2, wherein the multiphysics problem is configured for solving using a meshless method.

Statement 10. The method of any of statements 2-9, wherein the multiphysics problem is configured for solving using a machine learning model.

Statement 11. The method of any of statements 2-10, wherein the multiphysics problem comprises a fluid dynamics simulation problem.

Statement 12. The method of any of statements 2-11, wherein the multiphysics problem comprises a structural mechanics simulation problem.

Statement 13. The method of any of statements 2-12, wherein the multiphysics problem comprises a dynamics simulation problem.

Statement 14. The method of any of statements 2-13, wherein the multiphysics problem comprises a heat transfer simulation problem.

Statement 15. The method of any of statements 2-14, wherein the multiphysics problem comprises an acoustics simulation problem.

Statement 16. The method of any of statements 2-15, wherein the multiphysics problem comprises an electromagnetic simulation problem.

Statement 17. The method of any of statements 2-16, wherein the multiphysics problem comprises an electrochemistry simulation problem.

Statement 18. The method of any of statement 1, wherein the engineering problem comprises a design optimization problem.

Statement 19. The method of statement 18, wherein the design optimization problem comprises a topology optimization.

Statement 20. The method of any of statements 18-19, wherein the design optimization problem comprises a sizing optimization.

Statement 21. The method of any of statements 18-20, wherein the design optimization problem comprises a shape optimization.

Statement 22. The method of any of statements 18-21, wherein the design optimization problem comprises one or more of a plurality of objectives or a plurality of constraints.

Statement 23. The method of any of statements 18-22, wherein the design optimization problem comprises a multidisciplinary optimization method.

Statement 24. The method of any of statements 18-23, wherein the design optimization problem is configured for solving using a gradient-based optimization method.

Statement 25. The method of any of statements 18-24, wherein the design optimization problem is configured for solving using an evolutionary optimization method.

Statement 26. The method of any of statements 18-25, wherein the design optimization problem is configured for solving using an annealing-based optimization method.

Statement 27. The method of any of statements 18-26, wherein the design optimization problem is configured for solving using a surrogate optimization method.

Statement 28. The method of statement 27, wherein the surrogate optimization method comprises a machine learning model.

Statement 29. The method of statement 28, wherein the machine learning model comprises a neural network.

Statement 30. The method of any of statements 18-29 wherein the design optimization problem is configured for solving using a Design of Experiment method.

Statement 31. The method of any of statements 18-30, wherein the design optimization problem is configured for solving using linear programming or non-linear programming.

Statement 32. The method of any of statements 18-31, wherein the design optimization problem is configured for solving using a response surface method.

Statement 33. The method of any of statements 1-32, further comprising generating, using the processor, a graphic representation based on the output of the engineering model.

Statement 34. The method of statement 33, further comprising displaying the graphic representation on a display in electronic communication with the processor.

Statement 35. The method of any of statements 1-34, wherein the quantum processor comprises a plurality of quantum bits including the quantum bit.

Statement 36. The method of any of statements 1-35, further comprising determining, using an error correction module operating on the processor, an error.

Statement 37. The method of statement 36, further comprising determining, using the error correction module operating on the processor an engineering model correction based on the error.

Statement 38. The method of statement 37, wherein the determining of the engineering model correction is based on minimizing the error.

Statement 39. The method of statement 38, further comprising applying, using the processor, the engineering model correction to the engineering model to yield a corrected engineering model.

Statement 40. The method of statement 39, further comprising: applying, using the processor, the input to the corrected engineering model; generating, using the processor, a corrected quantum input based on the quantum algorithm of the corrected engineering model; communicating, using the processor, the corrected quantum input to the quantum bit interface module; receiving, at the processor, a corrected quantum output resulting from measuring the quantum bit; and determining, using the processor, a corrected output of the engineering model.

Statement 41. The method of any of statements 1-40, wherein the quantum processor comprises a quantum logic gate comprising the quantum bit.

Statement 42. The method of any of statements 1-41, wherein the quantum computing system further comprises a graphics processing unit.

Statement 43. The method of any of statements 1-42, wherein the quantum computing system further comprises a tensor processing unit.

Statement 44. The method of any of statements 1-43, wherein the quantum computing system further comprises a field-programmable gate array.

Statement 45. The method of any of statements 1-40, wherein the quantum computing system further comprises at least one of a graphics processing unit, a tensor processing unit, or a field-programmable gate array, wherein the processor, the quantum processor, and the at least one of the graphics processing unit, the tensor processing unit, or the field-programmable gate array are configured in a high-performance computing heterogeneous architecture.

Statement 46. The method of any of statements 1-45, wherein the quantum processor is an emulated quantum processor.

Statement 47. The method of any of statements 1-46, wherein the quantum processor is remote from the processor.

Statement 48. The method of any of statements 1-47, wherein communicating the quantum input using the processor to the quantum bit interface module is via a network.

Statement 49. The method of statement 48, wherein the network is the internet.

Statement 50. A system for solving an engineering problem using quantum computing, comprising: a quantum computing system including: a processor configured for classical binary computing operation; a quantum processor configured for quantum computing operation, comprising: a quantum bit configured for superposition and entailment; and a quantum bit interface module configured to receive a quantum input from the processor, manipulate the quantum bit based on the quantum input, determine an quantum output by measuring the quantum bit, and output the measurement of the quantum bit to the processor; and an electronic storage device in electronic communication with the processor having an engineering model stored thereon, wherein the engineering model comprises a quantum algorithm; wherein the quantum computing system is configured to perform a method including: receiving, at the processor, an input for the engineering problem; retrieving, using the processor, from the electronic storage device, the engineering model; applying, using the processor, the input to the engineering model; generating, using the processor, the quantum input based on the quantum algorithm; communicating, using the processor, the quantum input to the quantum bit interface module; receiving, at the processor, the quantum output resulting from measuring the quantum bit; and determining, using the processor, an output of the engineering model.

Statement 51. The system of statement 50, wherein the engineering problem comprises a multiphysics problem.

Statement 52. The system of statement 51, wherein the multiphysics problem includes a partial differential equation.

Statement 53. The system of any of statements 51-52, wherein the multiphysics problem is configured for solving using a finite element method, a finite volume method, a finite difference method, a Boundary Element method, a spectral method, a meshless method, or a machine learning model.

Statement 54. The system of any of statements 51-53, wherein the multiphysics problem comprises a fluid dynamics simulation problem, a structural mechanics simulation problem, a dynamics simulation problem, a heat transfer simulation problem, an acoustics simulation problem, an electromagnetic simulation problem, or an electrochemistry simulation problem.

Statement 55. The system of statement 50, wherein the engineering problem comprises a design optimization problem.

Statement 56. The system of statement 55, wherein the design optimization problem comprises a topology optimization, a sizing optimization, a shape optimization.

Statement 57. The system of any of statements 55-56, wherein the design optimization problem comprises one or more of a plurality of objectives or a plurality of constraints.

Statement 58. The system of any of statements 55-57, wherein the design optimization problem comprises a multidisciplinary optimization method.

Statement 59. The system of any of statements 55-58, wherein the design optimization problem is configured for solving using a gradient-based optimization method, an evolutionary optimization method, an annealing-based optimization method, a Design of Experiment method, a response surface method.

Statement 60. The system of any of statements 55-59, wherein the design optimization problem is configured for solving using a surrogate optimization method.

Statement 61. The system of any of statements 55-60, wherein the surrogate optimization method comprises a machine learning model.

Statement 62. The system of statement 61, wherein the machine learning model comprises a neural network.

Statement 63. The system of any of statements 55-62, wherein the design optimization problem is configured for solving using linear programming or non-linear programming.

Statement 64. The system of any of statements 50-63, wherein the method further comprises generating, using the processor, a graphic representation based on the output of the engineering model.

Statement 65. The system of any of statements 50-64, wherein the method further comprises displaying the graphic representation on a display in electronic communication with the processor.

Statement 66. The system of any of statements 50-65, wherein the quantum processor comprises a plurality of quantum bits including the quantum bit.

Statement 67. The system of any of statements 50-65, wherein the method further includes determining, using an error correction module operating on the processor, an error.

Statement 68. The system of statement 67, wherein the method further includes: determining, using the error correction module operating on the processor an engineering model correction based on the error; applying, using the processor, the engineering model correction to the engineering model to yield a corrected engineering model; applying, using the processor, the input to the corrected engineering model; generating, using the processor, a corrected quantum input based on the quantum algorithm of the corrected engineering model; communicating, using the processor, the corrected quantum input to the quantum bit interface module; receiving, at the processor, a corrected quantum output resulting from measuring the quantum bit; and determining, using the processor, a corrected output of the engineering model.

Statement 69. The system of statement 68, wherein the determining of the engineering model correction is based on minimizing the error.

Statement 70. The system of any of statements 50-69, wherein the quantum processor comprises a quantum logic gate comprising the quantum bit.

Statement 71. The system of any of statements 50-70, wherein the quantum computing system further comprises at least one of a graphics processing unit, a tensor processing unit, or a field-programmable gate array, wherein the processor, the quantum processor, and the at least one of the graphics processing unit, the tensor processing unit, or the field-programmable gate array are configured in a high-performance computing heterogeneous architecture.

Statement 72. The system of any of statements 50-71, wherein the quantum processor is an emulated quantum processor.

Statement 73. The system of any of statements 50-71, wherein the quantum processor is remote from the processor.

Statement 74. The system of statement 73, wherein communicating the quantum input using the processor to the quantum bit interface module is via a network.

Statement 75. A tangible, non-transient, computer-readable medium having instructions thereupon which when implemented by a processor cause the processor to perform a method for solving an engineering problem in a quantum computing system comprising: receiving, at the processor of the quantum computing system, an input for the engineering problem, wherein the quantum computing system includes: a processor configured for classical binary computing operation; a quantum processor configured for quantum computing operation, comprising: a quantum bit configured for superposition and entailment; and a quantum bit interface module configured to receive a quantum input from the processor, manipulate the quantum bit based on the quantum input, determine an quantum output by measuring the quantum bit, and output the measurement of the quantum bit to the processor; and an electronic storage device in electronic communication with the processor having an engineering model stored thereon, wherein the engineering model comprises a quantum algorithm; retrieving, using the processor, from the electronic storage device, the engineering model; applying, using the processor, the input to the engineering model; generating, using the processor, the quantum input based on the quantum algorithm; communicating, using the processor, the quantum input to the quantum bit interface module; receiving, at the processor, the quantum output resulting from measuring the quantum bit; and determining, using the processor, an output of the engineering model.

Statement 76. The tangible, non-transient, computer-readable medium of statement 75, wherein the engineering problem comprises a multiphysics problem.

Statement 77. The tangible, non-transient, computer-readable medium of statement 76, wherein the multiphysics problem includes a partial differential equation.

Statement 78. The tangible, non-transient, computer-readable medium of any of statements 76-77, wherein the multiphysics problem is configured for solving using a finite element method, a finite volume method, a finite difference method, a Boundary Element method, a spectral method, a meshless method, or a machine learning model.

Statement 79. The tangible, non-transient, computer-readable medium of any of statements 76-78, wherein the multiphysics problem comprises a fluid dynamics simulation problem, a structural mechanics simulation problem, a dynamics simulation problem, a heat transfer simulation problem, an acoustics simulation problem, an electromagnetic simulation problem, or an electrochemistry simulation problem.

Statement 80. The tangible, non-transient, computer-readable medium of statement 75, wherein the engineering problem comprises a design optimization problem.

Statement 81. The tangible, non-transient, computer-readable medium of statement 80, wherein the design optimization problem comprises a topology optimization, a sizing optimization, a shape optimization.

Statement 82. The tangible, non-transient, computer-readable medium of any of statements 80-81, wherein the design optimization problem comprises one or more of a plurality of objectives or a plurality of constraints.

Statement 83. The tangible, non-transient, computer-readable medium of any of statements 80-82, wherein the design optimization problem comprises a multidisciplinary optimization method.

Statement 84. The tangible, non-transient, computer-readable medium of any of statements 80-83, wherein the design optimization problem is configured for solving using a gradient-based optimization method, an evolutionary optimization method, an annealing-based optimization method, a Design of Experiment method, a response surface method.

Statement 85. The tangible, non-transient, computer-readable medium of any of statements 80-84, wherein the design optimization problem is configured for solving using a surrogate optimization method.

Statement 86. The tangible, non-transient, computer-readable medium of statement 85, wherein the surrogate optimization method comprises a machine learning model.

Statement 87. The tangible, non-transient, computer-readable medium of statement 86, wherein the machine learning model comprises a neural network.

Statement 88. The tangible, non-transient, computer-readable medium of any of statements 80-87, wherein the design optimization problem is configured for solving using linear programming or non-linear programming.

Statement 89. The tangible, non-transient, computer-readable medium of any of statements 75-89, wherein the method further comprises generating, using the processor, a graphic representation based on the output of the engineering model.

Statement 90. The tangible, non-transient, computer-readable medium of statement 89, wherein the method further comprises displaying the graphic representation on a display in electronic communication with the processor.

Statement 91. The tangible, non-transient, computer-readable medium of any of statements 75-90, wherein the method further includes determining, using an error correction module operating on the processor, an error.

Statement 92. The tangible, non-transient, computer-readable medium of statement 91, wherein the method further includes: determining, using the error correction module operating on the processor an engineering model correction based on the error; applying, using the processor, the engineering model correction to the engineering model to yield a corrected engineering model; applying, using the processor, the input to the corrected engineering model; generating, using the processor, a corrected quantum input based on the quantum algorithm of the corrected engineering model; communicating, using the processor, the corrected quantum input to the quantum bit interface module; receiving, at the processor, a corrected quantum output resulting from measuring the quantum bit; and determining, using the processor, a corrected output of the engineering model.

Statement 93. The tangible, non-transient, computer-readable medium of statement 92, wherein the determining of the engineering model correction is based on minimizing the error.

Various characteristics, advantages, implementations, embodiments, and/or examples relating to the invention have been described in the foregoing description with reference to the accompanying drawings. However, the above description and drawings are illustrative only. The invention is not limited to the illustrated implementations, embodiments, and/or examples, and all implementations, embodiments, and/or examples of the invention need not necessarily achieve every advantage or purpose, or possess every characteristic, identified herein. Accordingly, various changes, modifications, or omissions may be effected by one skilled in the art without departing from the scope or spirit of the invention, which is limited only by the appended claims. Although example materials and dimensions have been provided, the invention is not limited to such materials or dimensions unless specifically required by the language of a claim. Elements and uses of the above-described implementations, embodiments, and/or examples can be rearranged and combined in manners other than specifically described above, with any and all permutations within the scope of the invention, as limited only by the appended claims.

In the claims, various portions may be prefaced with letter or number references for convenience. However, use of such references does not imply a temporal or ordered relationship not otherwise required by the language of the claims. Unless the phrase ‘means for’ or ‘step for’ appears in a particular claim or claim limitation, such claim or claim limitation should not be interpreted to invoke 35 U.S.C. § 112(f).

As used herein, satisfying a threshold may, depending on the context, refer to a value being greater than the threshold, greater than or equal to the threshold, less than the threshold, less than or equal to the threshold, equal to the threshold, and/or the like, depending on the context.

As used in the specification and in the claims, use of “and” to join elements in a list forms a group of all elements of the list. For example, a list described as comprising A, B, and C defines a list that includes A, includes B, and includes C. As used in the specification and in the claims, use of “or” to join elements in a list forms a group of at least one element of the list. For example, a list described as comprising A, B, or C defines a list that may include A, may include B, may include C, may include any subset of A, B, and C, or may include A, B, and C. Unless otherwise stated, lists herein are inclusive, that is, lists are not limited to the stated elements and may be combined with other elements not specifically stated in a list. As used in the specification and in the claims, the singular form of ‘a', 'an', and 'the’ include plural referents (e.g., one or more of the referent) unless the context clearly dictates otherwise.

It is to be expressly understood that the drawings are for the purpose of illustration and description only and are not intended as a definition of the limits of the invention.

It is to be expressly understood that the drawings are for the purpose of illustration and description only and are not intended as a definition of the limits of the invention.

Unless otherwise stated, any range of values disclosed herein sets out a lower limit value and an upper limit value, and such ranges include all values and ranges between and including the limit values of the stated range, and all values and ranges substantially within the stated range as defined by the order of magnitude of the stated range.

The inventors hereby state their intent to rely on the Doctrine of Equivalents to determine and assess the reasonably fair scope of their invention as pertains to any apparatus not materially departing from but outside the literal scope of the invention as set out in the following claims.

1. A method for solving an engineering optimization problem using classical computing and quantum computing, comprising:
providing:
a processor configured for classical binary computing operation; and
an electronic storage device in electronic communication with the processor having an engineering model stored thereon, wherein the engineering model comprises a quantum algorithm configured for solving the engineering optimization problem;
receiving, at the processor, an input for the engineering model;
retrieving, using the processor, from the electronic storage device, the engineering model;
applying, using the processor, the input to the engineering model;
generating, using the processor, a quantum input based on the quantum algorithm;
transmitting, using the processor, the quantum input to a quantum processor comprising a quantum logic gate including a quantum bit and configured for a quantum computing operation based on the quantum input;
receiving, at the processor, a quantum output resulting from measuring the quantum bit following the quantum computing operation; and
determining, using the processor, an output of the engineering model.

2-18. (canceled)

19. The method of claim 1, wherein the engineering optimization problem comprises a topology optimization, a sizing optimization, a shape optimization, or a parametric optimization.

20-23. (canceled)

24. The method of claim 1, wherein the engineering optimization problem is configured for solving using a quantum-based optimization method including a gradient-based optimization method, an evolutionary optimization method, an annealing-based optimization method, a Design of Experiment method, linear programming, non-linear programming, or a response surface method.

25-26. (canceled)

27. The method of claim 1, wherein the engineering optimization problem is configured for solving using a quantum-native surrogate optimization method or a quantum-emulated surrogate optimization method.

28. The method of claim 27, wherein the quantum-native surrogate optimization method or the quantum-emulated surrogate optimization method comprises a machine learning model.

29. The method of claim 28, wherein the machine learning model comprises a neural network.

30-32. (canceled)

33. The method of claim 1, further comprising generating, using the processor, a graphic representation based on the output of the engineering model.

34. The method of claim 33, further comprising displaying the graphic representation on a display in electronic communication with the processor.

35. (canceled)

36. The method of claim 1, further comprising determining, using an error correction module operating on the processor, an error.

37. The method of claim 36, further comprising:
determining, using the error correction module operating on the processor an engineering model correction based on minimizing the error;
applying, using the processor, the engineering model correction to the engineering model to yield a corrected engineering model having a corrected quantum algorithm;
applying, using the processor, the input to the corrected engineering model;
generating, using the processor, a corrected quantum input based on the corrected quantum algorithm;
transmitting, using the processor, the corrected quantum input to the quantum processor;
receiving, at the processor, a corrected quantum output resulting from measuring the quantum bit; and
determining, using the processor, a corrected output of the engineering model.

38-44. (canceled)

45. The method of claim 1, further comprising providing at least one of a graphics processing unit, a tensor processing unit, or a field-programmable gate array, wherein the processor, the quantum processor, and at least one of the graphics processing unit, the tensor processing unit, or the field-programmable gate array are configured in a high-performance computing heterogeneous architecture.

46. The method of claim 1, wherein the quantum processor is an emulated quantum processor emulated on a classical processor, the quantum logic gate is an emulated quantum logic gate emulated on the classical processor, the quantum bit is an emulated quantum bit emulated on the classical processor, and the quantum computing operation is an emulated quantum computing operation emulated on the classical processor.

47-49. (canceled)

50. A system for solving an engineering optimization problem using classical computing and quantum computing comprising:
a processor configured for classical binary computing operation; and
an electronic storage device in electronic communication with the processor having an engineering model stored thereon, wherein the engineering model comprises a quantum algorithm configured for solving the engineering optimization problem;
wherein the processor is configured to:
receive, an input for the engineering model;
retrieve, from the electronic storage device, the engineering model;
apply, the input to the engineering model;
generate, a quantum input based on the quantum algorithm;
transmit, the quantum input to a quantum processor comprising a quantum logic gate including a quantum bit and configured for a quantum computing operation based on the quantum input;
receive, a quantum output resulting from measuring the quantum bit following the quantum computing operation; and
determine, an output of the engineering model.

51-59. (canceled)

60. The system of claim 50, wherein the engineering optimization problem is configured for solving using a surrogate optimization neural network.

61-70. (canceled)

71. The system of claim 50, further comprising at least one of a graphics processing unit, a tensor processing unit, or a field-programmable gate array, wherein the processor, the quantum processor, and at least one of the graphics processing unit, the tensor processing unit, or the field-programmable gate array are configured in a high-performance computing heterogeneous architecture.

72. The system of claim 50, wherein the quantum processor is an emulated quantum processor emulated on a classical processor, the quantum logic gate is an emulated quantum logic gate emulated on the classical processor, the quantum bit is an emulated quantum bit emulated on the classical processor, and the quantum computing operation is an emulated quantum computing operation emulated on the classical processor.

73. The system of claim 50, further comprising a network interface in electronic communication with the processor, wherein transmitting the quantum input using the processor to the quantum processor is via the network interface over a network to a second network interface in electronic communication with the quantum processor.

74. (canceled).

75. A tangible, non-transitory, computer-readable medium having instructions thereupon which when implemented by a processor cause the processor configured for classical binary computing operation to perform a method for solving an engineering optimization problem in a quantum computing system comprising:
receiving, an input for an engineering model comprising a quantum algorithm;
retrieving from an electronic storage device in electronic communication with the processor having the engineering model stored thereon, the engineering model;
applying the input to the engineering model;
generating a quantum input based on the quantum algorithm;
transmitting the quantum input to the a quantum processor comprising a quantum logic gate including a quantum bit and configured for a quantum computing operation based on the quantum input;
receiving a quantum output resulting from measuring the quantum bit following the quantum computing operation; and
determining an output of the engineering model.

76-83. (canceled)

84. The tangible, non-transitory, computer-readable medium of claim 75, wherein the engineering optimization problem is configured for solving using a quantum-based optimization method including a gradient-based optimization method, an evolutionary optimization method, an annealing-based optimization method, a Design of Experiment method, or a response surface method.

85. The tangible, non-transitory, computer-readable medium of claim 75, wherein the engineering optimization problem is configured for solving using a surrogate optimization neural network.

86-93. (canceled)

94. The tangible, non-transitory, computer-readable medium of claim 75, wherein the quantum processor is an emulated quantum processor emulated on a classical processor, the quantum logic gate is an emulated quantum logic gate emulated on the classical processor, the quantum bit is an emulated quantum bit emulated on the classical processor, and the quantum computing operation is an emulated quantum computing operation emulated on the classical processor.
